(19) United States
(12) Patent Application Publication
(10) Pub. No.: US 2004/0012069 A1
(43) Pub. Date: Jan. 22, 2004

(54) Semiconductor device and manufacturing method for the same

(75) Inventor: Shu Shimizu, Hyogo (JP)

Correspondence Address: McDERMOTT, WILL & EMERY, 600 13th Street, N.W., Washington, DC, 20005-3096, US

(73) Assignee: MITSUBISHI DENKI KABUSHIKI KAISHA

(21) Appl. No.: 10/338,669

(22) Filed: Jan. 9, 2003

(30) Foreign Application Priority Data
Jul. 16, 2002 (JP) 2002-206881(P)

(51) Int. Cl. H01L 29/00

(52) U.S. Cl. 257/510

(57) ABSTRACT

There is provided a semiconductor device capable of preventing the driving performance of a transistor from lowering. The semiconductor device includes an intermediate insulating film which is provided on a main surface between a gate insulating film and an isolation insulating film and which has a third top surface, and a gate electrode provided on each of the first to third top surfaces. When the height from the main surface to the first top surface is denoted as h1, the height from the main surface to the second top surface is denoted as h2 and the height from the main surface to the third top surface is denoted as h3, the heights h1, h2 and h3 satisfy the relationship shown by h2<h3<h1.

### BACKGROUND OF THE INVENTION

1. Field of the Invention

The present invention relates to a semiconductor device and a manufacturing method for the same, and more particularly to a semiconductor device in which each element is isolated by means of a trench.

2. Description of the Background Art

In recent years, as increase in the integration of and improvement of performance of semiconductor devices have progressed, the development of shallow trench isolation (STI) technology that a trench is used to isolate each element has been processing.

Such a technology using STI is disclosed in, for example, Japanese Patent Laying-Open No. 2000-306989. FIG. 12 is a cross sectional view of a semiconductor substrate for describing a conventional shallow trench isolation disclosed in the above described publication. With reference to FIG. 12, a pad oxide film 112 and a silicon nitride film (not shown) are formed on the surface of a silicon substrate 111 according to conventional shallow trench isolation. Lithographic technology and etch back technology are used to form a trench 113 on silicon substrate 111. Next, an insulating film 114 is filled into trench 113 by means of a chemical vapor deposition method (hereinafter referred to as CVD). After that, excess insulating film 114 is removed from silicon substrate 111 by means of chemical mechanical polishing (CMP) so that the surface is made planar. Furthermore, the silicon nitride film (not shown) used as a polishing stopper is removed by means of etch back.

Next, a sacrificial oxide film is formed in order to improve the film quality of the gate oxide film. First, pad oxide film 112 is removed by means of wet etching using diluted hydrofluoric acid. After that, the sacrificial oxide film is formed on the surface of silicon substrate 111 by means of a thermal oxidation method and, after that, this sacrificial oxide film is removed by means of wet etching using diluted hydrofluoric acid. After that, a gate oxide film (not shown) is formed on the surface of silicon substrate 111.

According to the conventional manufacturing method for an STI, as described above, wet etching using diluted hydrofluoric acid is carried out in order to remove a pad oxide film, a sacrificial oxide film and the like. This wet etching is isotropic. FIG. 13 is a cross sectional view showing a semiconductor substrate for describing a problem arising in conventional technology. With reference to FIG. 13, the sidewall portion of insulating film 114 is etched at the time of wet etching so that a recess 115 is generated between silicon substrate 111 and insulating film 114. When a gate oxide film and a gate electrode are formed in the state where recess 115 is generated, there has such a problem that this gate electrode is formed in recess 115 so that electrical field concentration generates in this portion, thereby the characteristics of the transistor are deteriorated.

### SUMMARY OF THE INVENTION

Therefore, the present invention is made in order to solve the above described problem and an object thereof is to provide a semiconductor device in which no recesses are generated between a trench and a semiconductor substrate and a manufacturing method for the same.

A semiconductor device according to the present invention includes: a semiconductor substrate having a main surface on which a trench is formed; an isolation insulating film into which the trench is filled and which has a first top surface; a gate insulating film formed on the main surface, and having a second top surface; an intermediate insulating film formed on the main surface between the gate insulating film and the isolation insulating film, and having a third top surface; and a gate electrode formed on each of the first to third surfaces. The isolation insulating film, the gate insulating film and the intermediate insulating film have approximately the same composition. When the height from the main surface to the first top surface is denoted as h1, the height from the main surface to the second top surface is denoted as h2 and the height from the main surface to the third top surface is denoted as h3, the heights h1, h2 and h3 satisfy the relationship shown by h2<h3<h1.

In the semiconductor device constituted in such a manner, the isolation insulating film, the gate insulating film and the intermediate insulating film have approximately the same composition. Therefore, a uniform electrical field can be formed in the semiconductor substrate beneath these insulating films. Furthermore, the heights of the top surfaces become greater as the position thereof approaches the isolation insulating film from the gate insulating film via the intermediate insulating film. Therefore, no recesses are formed in the insulating films. As a result, when a gate electrode is formed in these insulating films, the generation of electrical field concentration can be prevented so that the characteristics of the transistor do not become deteriorated.

In addition, the first to third top surfaces are preferably formed in a sequential step manner and the first to third top surfaces are formed approximately parallel to the main surface.

In this case, the first to third top surfaces are formed in a sequential step manner and each of these steps is approximately parallel to the main surface. Therefore, the gate electrode can easily be formed on top of these first to third top surfaces. As a result, the electrical field concentration in the gate electrode can be further relaxed.

A manufacturing method for a semiconductor device according to the present invention, includes the steps of: forming a trench on a main surface of a semiconductor substrate; forming an isolation insulating film into which the trench is filled; forming a first insulating film continuing to the isolation insulating film and covering the main surface; forming a mask layer, which covers a portion of the first insulating film continuing to the isolation insulating film and which exposes the remaining portion of the first insulating film, on the first insulating film; exposing the main surface by etching the portion of the first insulating film, which has been exposed through the mask layer, using the mask layer as a mask; forming a gate insulating film on the exposed main surface while forming an intermediate insulating film by increasing the thickness of the first insulating film which remains between the isolation insulating film and the gate insulating film; and forming a gate electrode on each of the gate insulating film, the intermediate insulating film and the isolation insulating film.

According to the manufacturing method for a semiconductor device of the present invention, constituted in such a manner, the gate insulating film is formed on the exposed main surface while the intermediate insulating film is formed by increasing the thickness of the first insulating film remaining between the isolation insulating film and the gate insulating film. As a result, the thicknesses of the insulating films increases as the position thereof approaches the isolation insulating film, from the gate insulating film via the intermediate insulating film. Therefore, no recesses are generated in the insulating films. As a result, the generation of electrical field concentration due to a recess can be prevented.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view of a semiconductor device according to a first embodiment of the present invention;

FIG. 2 is a cross sectional view taken along line II-II of FIG. 1;

FIG. 3 is a cross sectional view taken along line III-III of FIG. 1;

FIGS. 4 to 7 are cross sectional views showing first to fourth steps of a manufacturing method for the semiconductor device shown in FIG. 1;

FIG. 8 is a cross sectional view of a semiconductor device according to a second embodiment of the present invention;

FIGS. 9 to 11 are cross sectional views showing first to third steps of a manufacturing method for the semiconductor device shown in FIG. 8;

FIG. 12 is a cross sectional view of a semiconductor substrate for describing a conventional shallow trench isolation; and

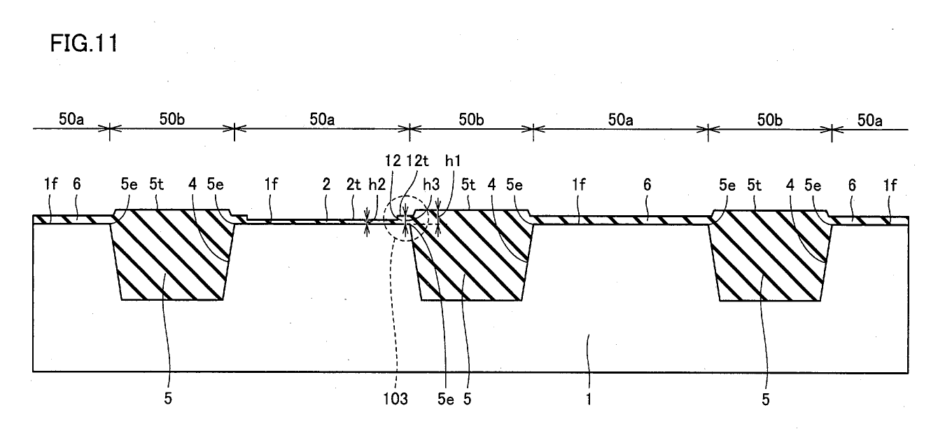

FIG. 13 is a cross sectional view, showing a semiconductor substrate, for describing a problem that arises in the conventional technology.

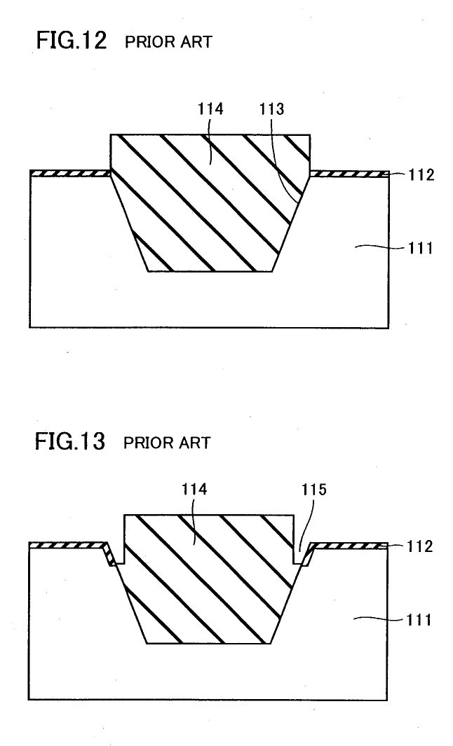

### DESCRIPTION OF THE PREFERRED EMBODIMENTS

In the following, embodiments of the present invention will be described with reference to the drawings. Here, the same reference symbols are attached to the same or corresponding parts and the descriptions thereof will not be repeated.

### First Embodiment

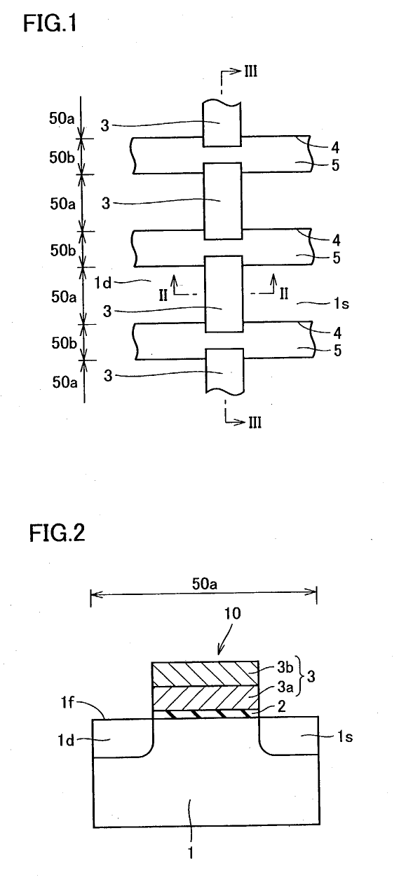

With reference to FIG. 1, a plurality of trenches 4 extending in one direction is formed in a silicon substrate in a semiconductor device according to a first embodiment of the present invention. Each of the plurality of trenches 4 extends parallel to one another.

Isolation insulating films made of silicon oxide films are formed within trenches 4, and each trench 4 and each isolation insulating film 5 isolate adjacent regions on the silicon substrate from one another. That is, respective elements are isolated from one another by means of STIs in this semiconductor device. Active regions 50a in which semiconductor elements are formed and isolation regions 50b for isolating the respective active regions 50a from one another are formed in an alternating manner.

Gate electrodes 3 are formed so as to extend in the direction approximately orthogonal to the direction in which trenches 4 extend. Gate electrodes 3 are formed so as to be divided into islands above isolation insulating films 5. A source region is and a drain region 1d are formed on the both sides of each gate electrode 3 so that a field effect transistor is constituted.

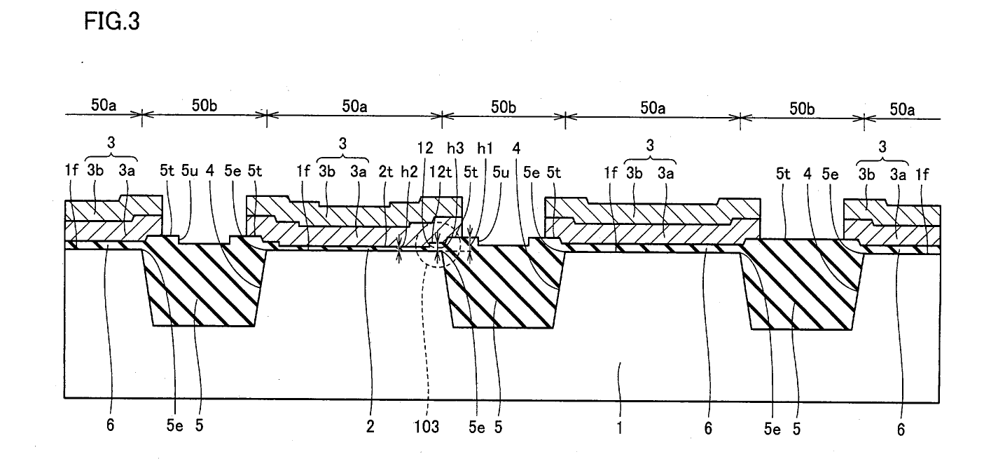

With reference to FIG. 2, a gate electrode 3 is formed on the surface of silicon substrate 1 with a gate insulating film 2 interposed. Gate electrode 3 is formed of a doped polysilicon film 3a to which phosphorus is doped and a tungsten silicide film 3b made of tungsten silicide. Source region is and drain region 1d are formed on the main surface of silicon substrate 1 in the both sides of gate electrode 3. Source region 1s and drain region 1d are constituted by an n-type or p-type impurity region. Gate electrode 3 formed on a main surface 1f with gate insulating film 2 interposed and source region 1s and drain region 1d formed in silicon substrate 1 on the both sides of gate electrode 3 constitute a field effect transistor 10.

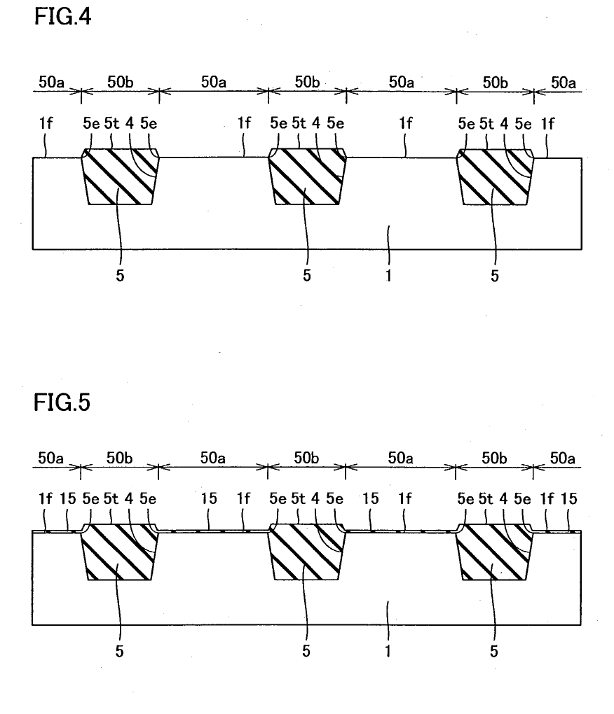

With reference to FIG. 3, the semiconductor device according to the first embodiment of the present invention is provided with silicon substrate 1 as a semiconductor substrate having main surface 1f and including trench 4 formed in main surface 1f, isolation insulating film 5 into which trench 4 is filled and which has a first top surface 5t, gate insulating film 2 formed on main surface 1f and having a second top surface 2t, an intermediate insulating film 12 formed on main surface 1f between gate insulating film 2 and isolation insulating film 5 and having a third top surface 12t, and gate electrode 3 provided on each of the first to third top surfaces 5t, 2t and 12t.

Isolation insulating film 5, gate insulating film 2 and intermediate insulating film 12 are constituted by silicon oxide films having approximately the same composition. When the height from main surface 1f to first top surface 5t is denoted as h1, the height from main surface 1f to second top surface 2t is denoted as h2 and the height from main surface 1f to third top surface 12t is denoted as h3, heights h1, h2 and h3 satisfy the relationship shown as h2<h3<h1.

First to third top surfaces 5t, 2t and 12t are formed in a sequential step manner and first to third top surfaces 5t, 2t and 12t are formed approximately parallel to main surface 1f.

Trenches 4 are formed at equal intervals in the surface of silicon substrate 1, and isolation insulating films 5 made of silicon oxide films are formed in the surface of silicon substrate 1 so that trenches 4 are filled thereinto.

Gate insulating film 2, which has a predetermined thickness and which is made of a silicon oxide film, a gate insulating film 6, which has a thickness greater than that of gate insulating film 2 and which is made of a silicon oxide film, are formed on main surface 1f of silicon substrate 1. A semiconductor element is formed on each area of main surface 1f.

Intermediate insulating film 12, which is made of a silicon oxide film and which continues to gate insulating film 2 and to an edge portion 5e of isolation insulating film 5, is formed between isolation insulating film 5 and gate insulating film 2. Intermediate insulating film 12 is formed on main surface 1f and has third top surface 12t. Third top surface 12t functions so as to moderate the step between first top surface 5t and second top surface 2t. Intermediate insulating film 12 is formed in a portion surrounded by broken line 103 in FIG. 3.

Gate electrode 3 is formed on gate insulating films 2 and 6, intermediate insulating film 12 and isolation insulating film 5. Adjacent gate electrodes 3 are isolated from each other on isolation insulating film 5. A recess 5u is formed in an isolation insulating film 5 so that recess 5u is exposed through gate electrodes 3.

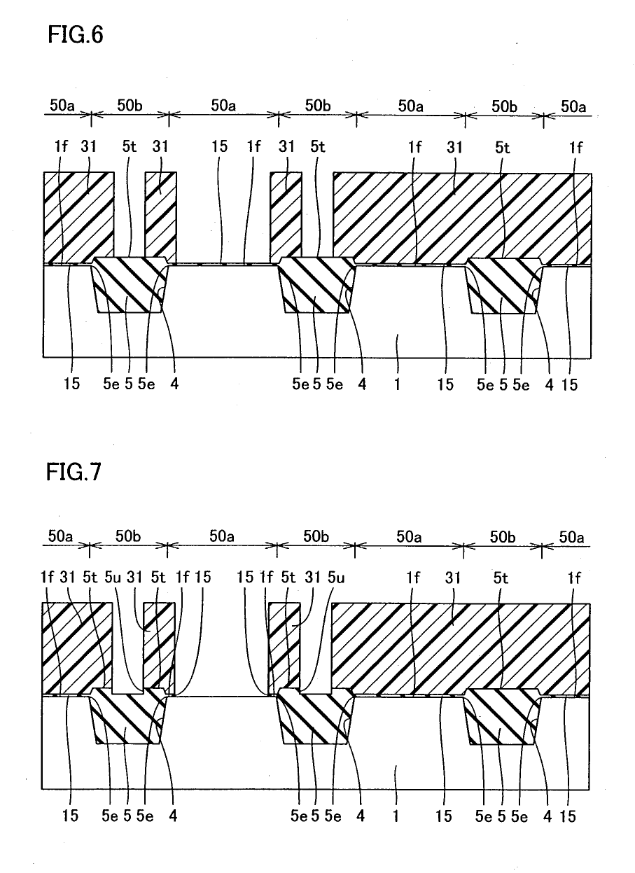

Next, a manufacturing method for the semiconductor device shown in FIGS. 1 to 3 will be described. With reference to FIG. 4, first, a resist pattern is formed on main surface 1f of silicon substrate 1, and main surface 1f is etched in accordance with this resist pattern. Thereby, trenches 4 are formed. Isolation insulating films 5 made of silicon oxide films are formed so that trenches 4 are filled thereinto. Next, n-type wells and p-type wells (not shown) are formed by means of ion implantation and, after that, thermal oxide films formed on main surface 1f of silicon substrate 1 are removed by means of diluted hydrofluoric acid.

First insulating films 15 made of thermal oxide films having a thickness of approximately 10 nm are formed on main surface 1f of silicon substrate 1. First insulating films 15 continue to edge portions 5e of isolation insulating films 5 and cover main surface 1f.

With reference to FIG. 6, a resist pattern 31 having a predetermined pattern is formed on silicon substrate 1. Resist pattern 31 exposes portions of isolation insulating films 5. Resist pattern 31 also exposes first insulating film 15. An object of forming resist pattern 31 having such a pattern is the provision of a gate insulating film of a MOS (Metal Oxide Semiconductor) transistor with a portion having a great thickness and a portion having a small thickness, respectively. At this time, edge portions of the isolation insulating films, that is, border portions between isolation regions 50b and active regions 50a are covered, without fail, with resist pattern 31. That is, first insulating film 15 which continues to isolation insulating films 5 and covers main surface 1f is formed. After that, resist pattern 31, as a mask layer, is formed on first insulating film 15 so that portions of first insulating film 15, which continues to isolation insulating films 5, are covered and the remaining portion of first insulating film 15 is exposed.

With reference to FIG. 7, first insulating film 15, which is a thermal oxide film, is removed by means of diluted hydrofluoric acid using resist pattern 31 as a mask. In the preprocess, all of the field edges are covered with resist pattern 31 and, therefore, the corners of isolation insulating films 5 can be prevented from becoming rounded due to over etching by means of diluted hydrofluoric acid. In this process, main surface 1f is exposed by etching the portion of first insulating film 15 that is exposed through resist pattern 31, using resist pattern 31 as a mask.

With reference to FIG. 3, after the removal of resist pattern 31, a thermal oxide film having a thickness of approximately 5 nm is formed on main surface 1f of silicon substrate 1 so that gate insulating film 2 is formed. Further oxidation is carried out under the condition where gate insulating films remain on main surface 1f of silicon substrate 1 at the field edges that have been covered with resist pattern 31 in the previous process and, therefore, gate insulating films 6, which are thicker than gate insulating film 2, are formed in the portions that have been covered with resist pattern 31. In addition, edge portions 5e, which are field edges, of the remaining first insulating films 15 are oxidized so that intermediate insulating films 12, which continue to gate insulating film 2 and to isolation insulating films 5, are formed.

Doped polysilicon to which phosphorus has been doped and a tungsten silicide film are deposited in order to form gate electrodes of MOS transistors. A resist pattern is formed on the tungsten silicide film and, then, the doped polysilicon film and the tungsten silicide film are dry etched in accordance with this resist pattern, thereby forming gate electrodes 3 of MOS transistors that are constituted by doped polysilicon films 3a and tungsten silicide films 3b. After that, impurity ions are implanted in silicon substrate 1 by means of ion implantation using gate electrodes 3 as a mask so that source and drain regions are formed. After that, an interlayer isolation film (not shown) is formed and, then, contact holes, metal wires and the like are formed in this interlayer insulating film.

That is, in the process shown in FIG. 3, gate insulating film 2 is formed on exposed main surface 1f while the thickness of first insulating films 15 which have remained between isolation insulating films 5 and gate insulating film 2 is increased so as to form intermediate insulating films 12. Gate electrodes 3 are formed on gate insulating film 2, intermediate insulating films 12 and isolation insulating films 5.

In the semiconductor device according to the present invention having such a configuration, as shown in FIG. 3, the thicknesses of the insulating films made of silicon oxide films increase in a step-by-step manner from gate insulating film 2 to isolation insulating film 5 via intermediate insulating film 12. As a result, unlike in the prior art, the etched portions of isolation insulating films 5 are not rounded. As a result, even when gate electrodes 3 are formed on such insulating films, the generation of electrical field concentration in gate electrodes 3 can be prevented so that deterioration in the performance of the field effect transistors can be prevented.

### Second Embodiment

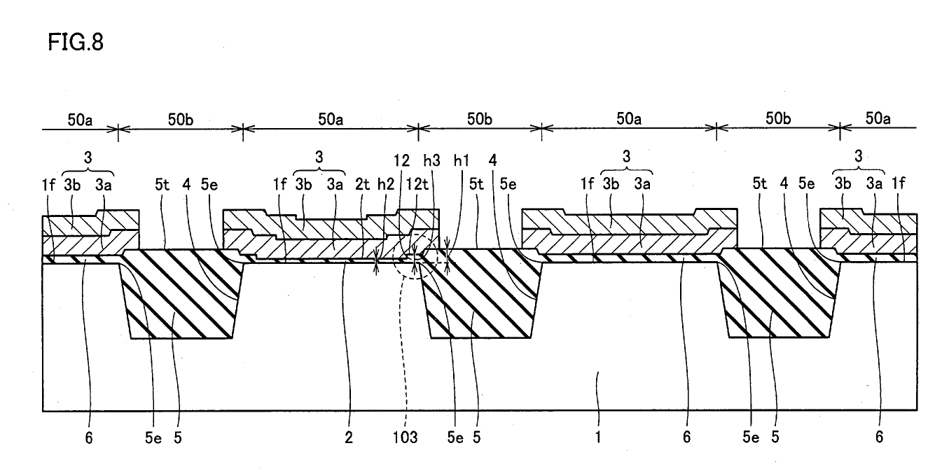

With reference to FIG. 8, the semiconductor device according to a second embodiment of the present invention differs from the semiconductor device according to the first embodiment in the point that recesses 5u are not provided in isolation insulating films 5 in the semiconductor device according to the second embodiment. Since recesses 5u are not provided in isolation insulating films 5, the isolation insulating films are formed so that the heights of first top surfaces 5t are approximately uniform.

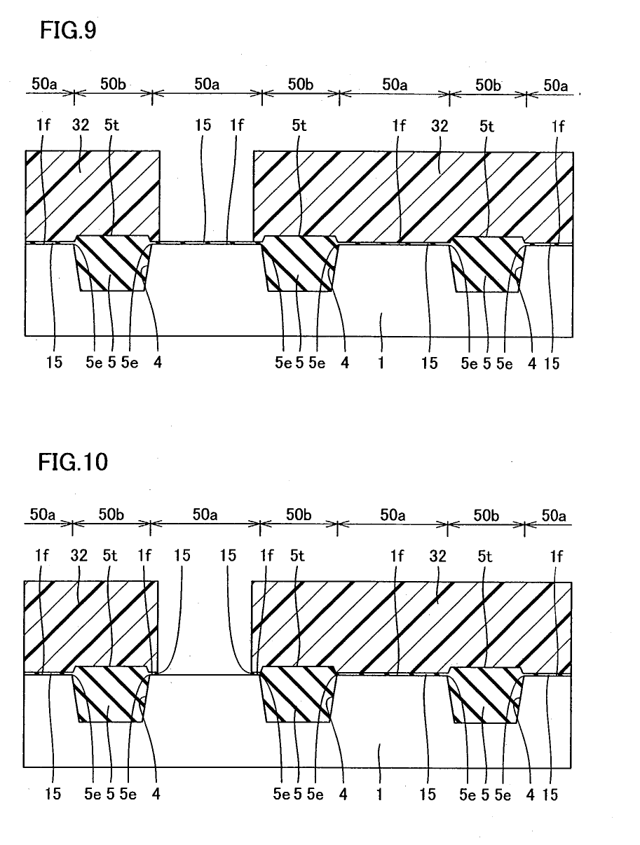

Next, a manufacturing method for the semiconductor device shown in FIG. 8 will be described. With reference to FIG. 9, first, trenches 4, isolation insulating films 5 and first insulating films 15 are formed in accordance with the similar process to that of the first embodiment. Next, a resist pattern 32 is formed on main surface 1f. All of the field edges, that is, edge portions 5e which are border portions between active regions 50a and isolation regions 50b and isolation insulating films 5 are covered with resist pattern 32.

With reference to FIG. 10, a first insulating film 15 is etched using resist pattern 32 as a mask. At this time, all of edge portions 5e, which are field edges, are covered with resist pattern 32 and, therefore, the corners of isolation insulating films 5 can be prevented from becoming rounded due to over etching with diluted hydrofluoric acid.

In addition, all isolation insulating films 5 are covered with resist pattern 32 and, therefore, isolation insulating films 5 do not become much thinner due to etching with diluted hydrofluoric acid. As a result, it becomes difficult for implanted ion species to pass through isolation insulating films 5 at the time of ion implantation for forming source and drain regions 1s and 1d.

With reference to FIG. 11, after the removal of resist pattern 31, a thermal oxide film having a thickness of approximately 5 nm is formed on main surface 1f of silicon substrate 1 so that gate insulating film 2 is formed. Further oxidation is carried out under the condition where gate insulating films remain on main surface 1f of silicon substrate 1 at the field edges, which have been covered with resist pattern 31 in the previous process and, therefore, gate insulating films 6 having thicknesses thicker than those of gate insulating film 2, are formed in the portions that have been covered with resist pattern 31. In addition, the remaining first insulating films 15 are oxidized at edge portions 5e, which are the field edges, so that intermediate insulating films 12 which continue to gate insulating film 2 and isolation insulating films 5 are formed.

With reference to FIG. 8, doped polysilicon to which phosphorus has been doped and a tungsten silicide film are deposited in order to form gate electrodes of MOS transistors. A resist pattern is formed on the tungsten silicide film, and then the doped polysilicon film and the tungsten silicide film are dry etched in accordance with this resist pattern, thereby gate electrodes 3 of MOS transistors are formed of doped polysilicon films 3a and tungsten silicide films 3b. After that, impurity ions are implanted in silicon substrate 1 by means of ion implantation using gate electrodes 3 as a mask so that source and drain regions are formed. After that, an interlayer isolation film (not shown) is formed, and then contact holes, metal wires and the like are formed in this interlayer insulating film.

The semiconductor device according to the second embodiment of the present invention, having such a configuration, has the same effects as of the semiconductor device according to the first embodiment.

In addition, though an example wherein the gate insulating films, the intermediate insulating films and the isolation insulating films are silicon oxide films is shown in the above described embodiments, these films may be silicon nitride oxide films or the like that include nitrogen. Furthermore, the three types of insulating films described above need not be of the same composition but, rather, a combination of silicon oxide films and silicon nitride oxide films may be used. The isolation insulating films, the gate insulating films and the intermediate insulating films may have approximately the same composition and, therefore, any one or two of the isolation insulating films, the gate insulating films and the intermediate insulating films may be silicon nitride oxide films while the remaining films may be silicon oxide films. The isolation insulating films, the gate insulating films and the intermediate insulating films may all be silicon nitride oxide films.

According to the present invention, it is possible to provide a semiconductor device in which electrical field concentration is prevented and the performance of transistors does not become deteriorated.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device comprising:
a semiconductor substrate having a main surface on which a trench is formed;
an isolation insulating film into which said trench is filled and which has a first top surface;
a gate insulating film formed on said main surface, and having a second top surface;
an intermediate insulating film formed on said main surface between said gate insulating film and said isolation insulating film, and having a third top surface; and
a gate electrode formed on each of said first to third surfaces, wherein
said isolation insulating film, said gate insulating film and said intermediate insulating film have approximately the same composition, and
when the height from said main surface to said first top surface is denoted as h1, the height from said main surface to said second top surface is denoted as h2 and the height from said main surface to said third top surface is denoted as h3, said heights h1, h2 and h3 satisfy the relationship shown by h2<h3<h1.

2. The semiconductor device according to claim 1, wherein
said first to third top surfaces are formed in a sequential step manner, and
said first to third top surfaces are formed approximately parallel to said main surface.

3. A manufacturing method for a semiconductor device, comprising the steps of:
forming a trench on a main surface of a semiconductor substrate;
forming an isolation insulating film into which said trench is filled;
forming a first insulating film continuing to said isolation insulating film and covering said main surface;
forming a mask layer, which covers a portion of said first insulating film continuing to said isolation insulating film and which exposes the remaining portion of said first insulating film, on said first insulating film;
exposing said main surface by etching the portion of said first insulating film, which has been exposed through said mask layer, using said mask layer as a mask;
forming a gate insulating film on said exposed main surface while forming an intermediate insulating film by increasing the thickness of said first insulating film which remains between said isolation insulating film and said gate insulating film; and
forming a gate electrode on each of said gate insulating film, said intermediate insulating film and said isolation insulating film.
